(19) United States
(12) Patent Application Publication
(10) Pub. No.: US 2009/0085224 A1
(43) Pub. Date: Apr. 2, 2009

(54) STACK-TYPE SEMICONDUCTOR PACKAGE

(75) Inventors: Ju-Il CHOI, Gyeonggi-do (KR); Hyun-Soo CHUNG, Gyeonggi-do (KR); In-Young LEE, Gyeonggi-do (KR); Ho-Jin LEE, Seoul (KR); Son-Kwan HWANG, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggi-do (KR)

(21) Appl. No.: 12/244,591

(22) Filed: Oct. 2, 2008

(30) Foreign Application Priority Data
Oct. 2, 2007 (KR) 2007-0099243

(51) Int. Cl. H01L 23/538; H01L 21/58

(52) U.S. Cl. 257/777; 438/109; 257/E23.169; 257/E21.505

(57) ABSTRACT

Provided is a stack-type semiconductor package including a base chip having a circuit formed on one of its surfaces, at least one stack chip having a circuit stacked on the base chip, an adhesive interposed between the base chip and the stack chip, and signal transmission members formed along a lateral surface of the stack chip. The fabrication process of this stack-type semiconductor package may be simplified and the number of process operations may be lessened, thereby reducing the production time and cost. Also, a state of electrical contact of a terminal with a signal transmission member may be solidified, thereby improving the reliability of the stack-type semiconductor package. Furthermore, new post-type signal transmission members are adopted instead of wires or electrodes so that the structural stability and productivity of the stack-type semiconductor package may be markedly enhanced.

### CROSS-REFERENCE TO RELATED PATENT APPLICATION

This application claims the benefit of Korean Patent Application No. 10-2007-0099243, filed on Oct. 2, 2007, in the Korean Intellectual Property Office, the disclosure of which is incorporated herein in its entirety by reference.

### BACKGROUND OF THE INVENTION

1. Field of the Invention

The present invention relates to a stack-type semiconductor package, and more particularly, to a stack-type semiconductor package in which a stack chip is stacked on a wafer for forming a base chip and signal transmission members are formed on a wafer level at one time, thereby simplifying a fabrication process and reducing the number of process operations.

2. Description of the Related Art

In general, packaging processes for semiconductor chips with microcircuits use a plastic resin or ceramic to encapsulate the semiconductor chip in part to protect the chips and microcircuits from outer environmental elements. In addition, these packaging processes may enable electrical connection of the semiconductor chips with outside components, and efficiently dissipate heat generated during operation of the internal semiconductor chip so as to ensure thermal and electrical reliability of the semiconductor chips.

Meanwhile, owing to the downscaling of electronic devices, semiconductor packages used for the electronic devices are showing the same tendency to become downscaled. In recent years, laborious research into flip-chip packages, wafer-level packages, and wafer-level stack packages has progressed centering on miniaturization of these semiconductor packages. In particular, the stack technology used for highly integrating a plurality of semiconductor chips has become complicated and the number of process operations has been greatly increased.

### SUMMARY OF THE INVENTION

The present invention provides a stack-type semiconductor package and a method of fabricating the same, wherein signal transmission members are formed on a wafer level at one time to simplify the fabrication process and lessen the number of process operations, thereby reducing the production time and cost. The stack-type semiconductor package may also have improved reliability and improved structural solidity and productivity.

According to an embodiment of the present invention, a stack-type semiconductor package includes a base chip having a circuit formed on one of its surfaces, at least one stack chip having a circuit stacked on the base chip, an adhesive is interposed between the base chip and the stack chip, and signal transmission members formed along a lateral surface of the stack chip.

### BRIEF DESCRIPTION OF THE DRAWINGS

The above and other features and advantages of the present invention will become more apparent by describing in detail exemplary embodiments thereof with reference to the attached drawings in which:

FIG. 1 is a perspective view of a stack-type semiconductor package according to an embodiment of the present invention;

FIG. 2 is a cross-sectional view of the stack-type semiconductor package shown in FIG. 1;

FIG. 3 is a cross-sectional view of a stack-type semiconductor package according to another embodiment of the present invention;

FIG. 4 is a flowchart of a method of fabricating a stack-type semiconductor package according to an embodiment of the present invention;

FIG. 5 is a plan view of a base chip circuit of a base wafer W1 according to an embodiment of the present invention;

FIG. 6 is a plan view of an adhesive formed on the base chip circuit of the base wafer W1 according to an embodiment of the present invention;

FIG. 7 is a plan view of an adhesive formed on the stack chip circuit of a stack wafer W2 according to an embodiment of the present invention;

FIG. 8 is a perspective view of individual stack chips cut along a stack cut line L2 of FIG. 7 according to an embodiment of the present invention;

FIG. 9 is a perspective view of individual stack chips stacked on the adhesive according to an embodiment of the present invention;

FIG. 10 is a perspective view of photoresist coated on a stack chip to form a signal transmission member along a lateral surface of the stack chip according to an embodiment of the present invention;

FIG. 11 is a perspective view of the signal transmission member formed along the lateral surface of the stack chip according to an embodiment of the present invention; and

FIG. 12 is a cross-sectional view of the base wafer W1, which is cut along a base cut line L1 according to an embodiment of the present invention.

### DETAILED DESCRIPTION

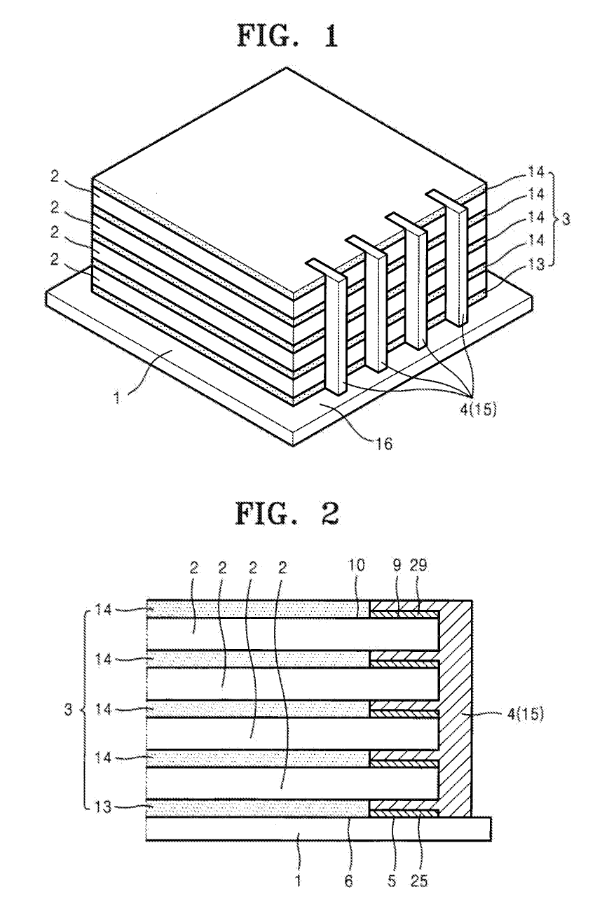

FIG. 1 is a perspective view of a stack-type semiconductor package according to an embodiment of the present invention. FIG. 2 is a cross-sectional view of the stack-type semiconductor package shown in FIG. 1.

Referring to FIGS. 1 and 2, a stack-type semiconductor package according to an embodiment of the present invention may include a base chip 1, at least one stack chip 2, an adhesive 3 substantially covering a top surface of each of the base chip 1 and the stack chips 2, and signal transmission members 4 for electrically connecting the base chip 1 and the stack chips 2.

Specifically, a circuit may be formed on one side of the base chip 1. Referring to FIG. 2, the circuit of the base chip 1 may include a base edge terminal 5 that extends to the signal transmission members 4 through a base edge terminal metal seed layer 25.

In this case, the base edge terminal 5 may not necessarily extend to the edge of the base chip 1. Thus, any kind of terminal that can extend to the signal transmission members 4 may be used instead of the base edge terminal 5.

In particular, it is exemplarily illustrated in FIGS. 1 and 2 that a support portion 16 for supporting the signal transmission members 4 may be formed along the outer portion of the base chip 1, and the base edge terminal 5 may be extended to the signal transmission members 4 through the base edge terminal metal seed layer 25.

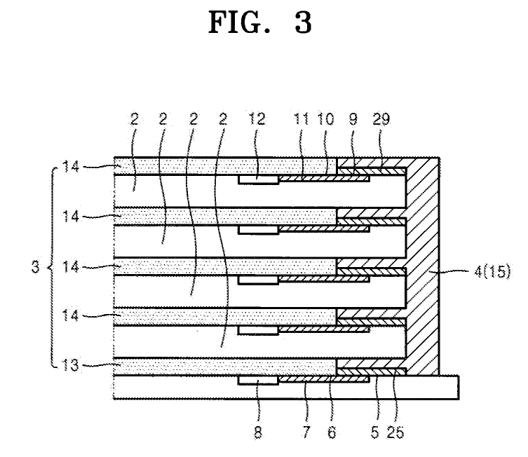

FIG. 3 is a cross-sectional view of a stack-type semiconductor package according to another embodiment of the present invention.

Referring to FIG. 3, a base edge pad 6 may be connected to the base edge terminal 5, and a base center pad 8 may be connected to the base edge pad 6 by a base connection circuit 7. In addition, various other shapes of paths may be designed on the circuit of the base chip 1. Referring again to FIGS. 1 and 2, at least one stack chip 2 may be stacked on the base chip 1, and a circuit may be formed on one side of the stack chip 2. Also, the circuit of the stack chip 2 may include a stack edge terminal 9 that extends to an outer portion of the stack chip 2.

In this case, the stack edge terminal 9 may not necessarily extend to the edge of the stack chip 2. Thus, any kind of terminal that can extend to the signal transmission members 4 may be used instead of the stack edge terminal 9.

Referring again to FIG. 3, a stack edge pad 10 may be connected to the stack edge terminal 9, and a stack center pad 12 may be connected to the stack edge pad 10 by a stack connection circuit 11. In addition, various other shapes of paths may be designed on the circuits of the stack chips 2.

Returning to FIGS. 1 and 2, the adhesive 3 may be installed between the base chip 1 and the stack chip 2. The adhesive 3 may include a base adhesive layer 13 substantially covering the circuit of the base chip 1 and a stack adhesive layer 14 substantially covering the circuit of the stack chip 2.

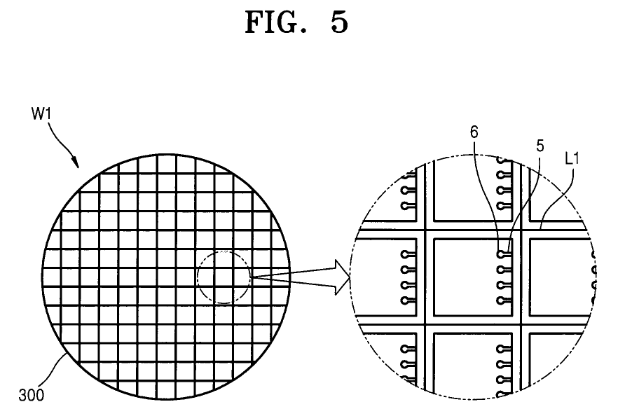

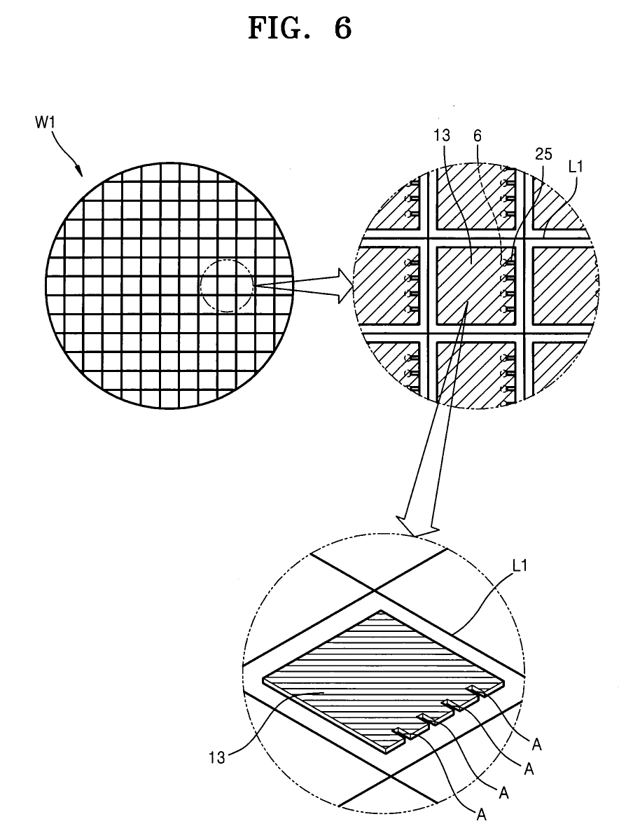

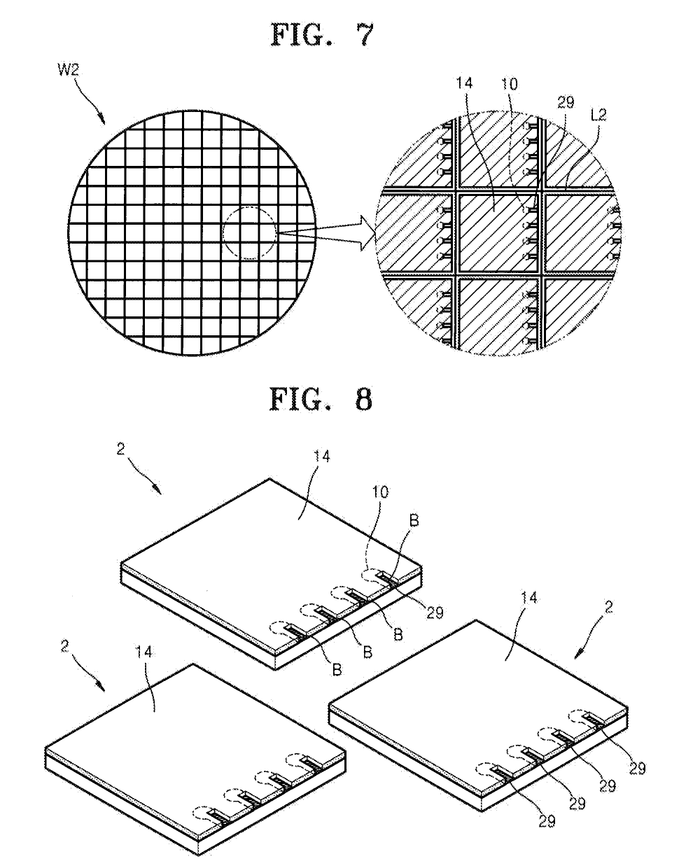

FIG. 5 is a plan view of a base chip circuit of a base wafer W1 according to an embodiment of the present invention. FIG. 6 is a plan view of an adhesive formed on the base chip circuit of the base wafer W1 according to an embodiment of the present invention. FIG. 7 is a plan view of an adhesive formed on the stack chip circuit of a stack wafer W2 according to an embodiment of the present invention. FIG. 8 is a perspective view of individual stack chips cut along a stack cut line L2 of FIG. 7 according to an embodiment of the present invention.

Referring to FIGS. 5, 6, 7, and 8, and referring again to FIGS. 1 and 2, the base adhesive layer 13 may protect the circuit of the base chip 1 and may also form a space A to expose one side of the base edge terminal 5 of the base chip 1 (FIG. 6). The stack adhesive layer 14 may protect the circuit of the stack chip 2 and may also form a space B to expose one side of the stack edge terminal 9 of the stack chip 2 (FIG. 8). In particular, the adhesive 3 may be a photosensitive adhesive capable of selectively forming patterns to form the above-described spaces A and B.

Specifically, the formation of the adhesive 3 may include coating a photosensitive adhesive capable of forming patterns on the base chip 1 and the stack chips 2, which may form either a photosensitized portion to which light is exposed, or an unphotosensitized portion to which light is not exposed, in portions of the coated photosensitive adhesive corresponding to the base edge terminals 5 and the stack edge terminals 9. Such selective photosensitization may facilitate a partial removal of the base adhesive layer 13 and the stack adhesive layer 14. Such an uncured photosensitized or unphotosensitized portion may be removed by etching.

The signal transmission members 4 may be formed along a lateral surface of the stack chip 2 so as to electrically connect the circuit of the base chip 1 and the circuit of the stack chip 2. The signal transmission members 4 may be conductive metal posts 15 substantially filling in the space A of the base adhesive layer 13 and the space B of the stack adhesive layer 14. The metal posts 15 may be formed through a plating process unlike conventional wire or electrode formation processes.

That is, the formation of the metal posts 15 may include forming base edge terminal metal seed layers 25 on the exposed base edge terminals 5 of the base chip 1 and stack edge terminal metal seed layers 29 on the exposed stack edge terminals 9 of the stack chip 2. The formation of the metal posts 15 may also include plating the metal seed layers with a metal component by substantially filling the space A of the base adhesive layer 13 and the space B of the stack adhesive layer 14.

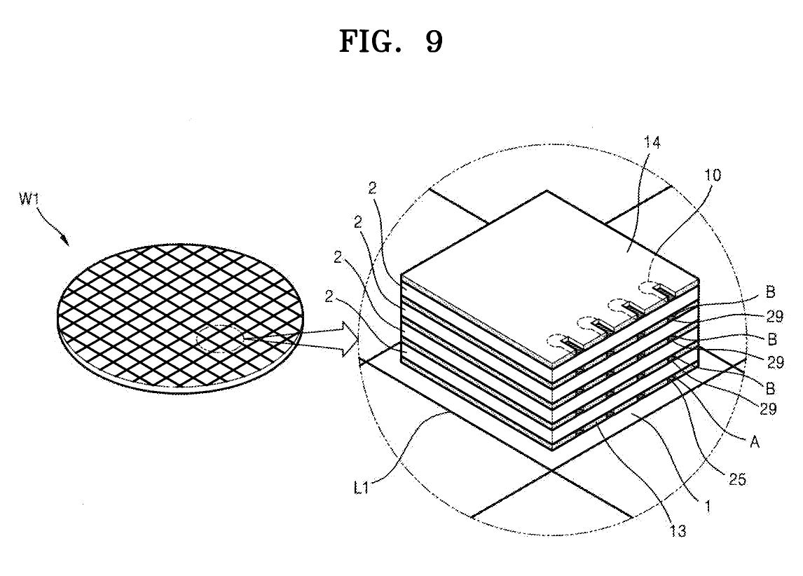

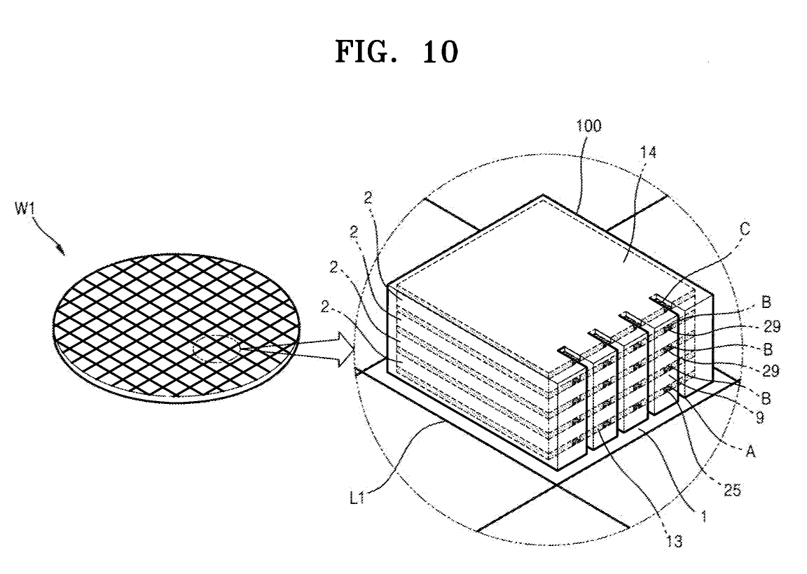

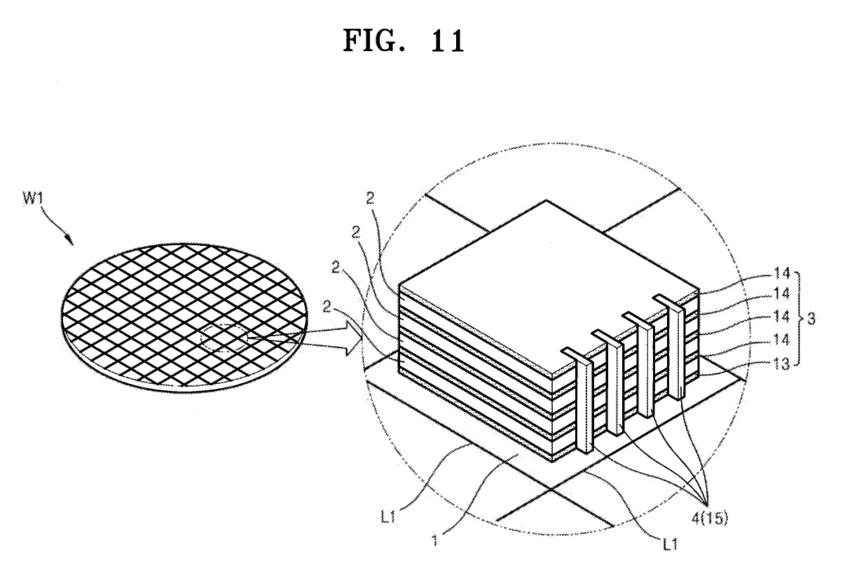

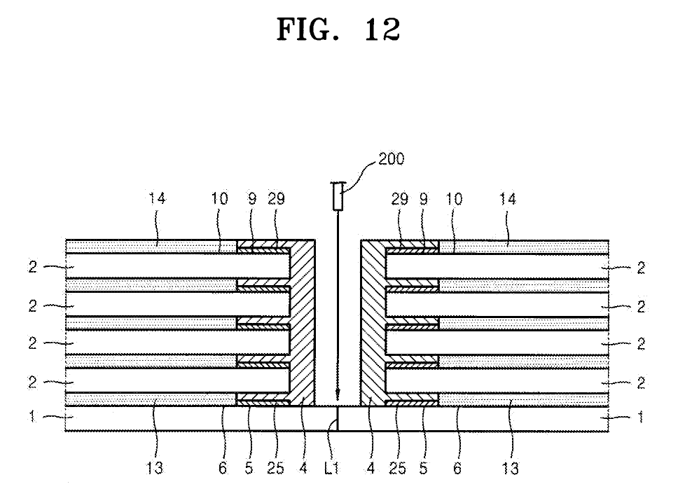

FIG. 9 is a perspective view of individual stack chips stacked on the adhesive according to an embodiment of the present invention. FIG. 10 is a perspective view of photoresist coated on a stack chip to form a signal transmission member along a lateral surface of the stack chip according to an embodiment of the present invention. FIG. 11 is a perspective view of the signal transmission member formed along the lateral surface of the stack chip according to an embodiment of the present invention.

Referring to FIGS. 9 and 10, the stack chip 2 may be substantially adhered, using the base adhesive layer 13, to the top surface of the circuit of the base chip 1 on the level of a base wafer W1 used for fabrication of the base chip 1. In this way, the plating process for forming the metal posts 15 may be performed on circuits of all base chips 1 and stack chips 2 at one time on a wafer level.

Accordingly, the foregoing plating process may be performed on all base chips 1 and stack chips 2 at one time on the level of the base wafer W1. Conventionally, the formation of signal transmission members may involve performing a lot of processes, such as a wire welding process, a solder ball welding process, or an electrode forming process, on an individual chip using a robot or a welding machine. However, according to an embodiment of the present invention, the signal transmission members 4 may be formed using a simple, one-time process, thereby greatly reducing the production time and cost.

During the plating process, the fine metal component may diffuse into and may substantially adhere to the spaces A and B formed in the base wafer W1 and stack chips 2. As a result, a connection structure for electrically connecting the base chip and the stack chip 2 may become very dense, solid, and highly durable, and highly reliable products using the stack-type semiconductor package may be produced according to an embodiment of the present invention.

Hereinafter, a method of fabricating a stack-type semiconductor package according to an embodiment of the present invention will be described.

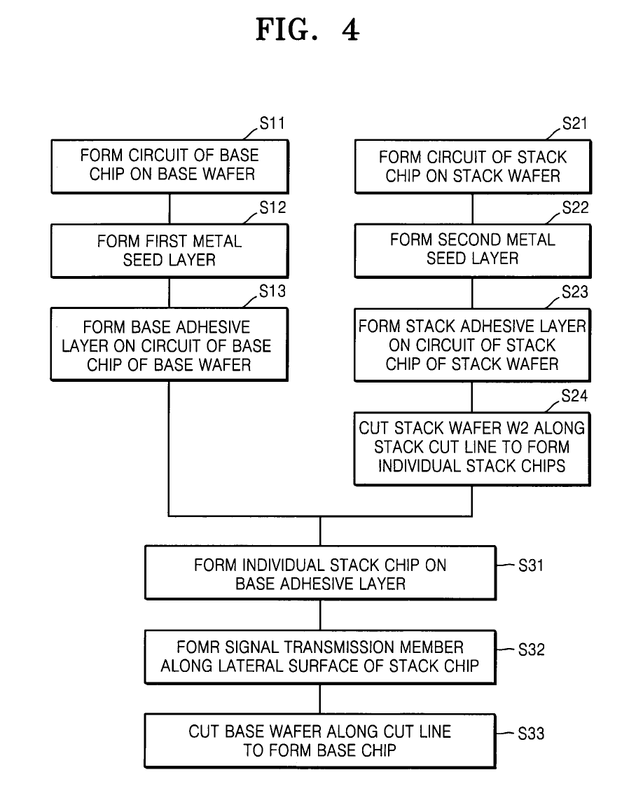

FIG. 4 is a flowchart of a method of fabricating a stack-type semiconductor package according to an embodiment of the present invention.

Referring to FIG. 4, at least one circuit of a base chip 1 may be formed on a base wafer W1 in operation S11. In operation S13, an adhesive 3 is formed on the circuit of the base chip 1 of the base wafer W1.

In operation S21, at least one circuit of a stack chip 2 may be formed on a stack wafer W2 used for fabrication of the stack chip 2. In operation S24, the stack wafer W2 may be cut along a stack cut line L2 to form individual stack chips 2.

In operation S31, the individual stack chips 2 may be stacked on the adhesive 3. In operation S32, a signal transmission member 4 may be formed along a lateral surface of the stack chip 2 so that the circuit of the base chip 1 of the base wafer W1 may be electrically connected to the circuit of the stack chip 2. In operation S33, the base wafer W1, which may include the signal transmission member 4, may be cut along a base cut line L1 to thereby complete the fabrication of the base chip 1 on which the stack chip 2 is stacked.

Referring again to FIG. 5, in operation S11, a base edge terminal 5, a base edge pad 6, and the base cut line L1 may be separately formed on the circuit of the base chip 1.

As shown in FIG. 4, operation S11 may include operation S12 in which a base edge terminal metal seed layer 25 may be formed on a portion of the edge of the circuit of the base chip 1, which corresponds to the base edge terminal 5, such that the base edge terminal 5 is plated with a metal component.

Operation S12 may include forming a first metal seed layer on the base wafer W1, coating photoresist on the first metal seed layer, exposing the photoresist to light, and etching the remaining portion of the first metal seed layer other than base edge terminal metal seed layer 25 corresponding to the base edge terminal 5.

In operation S11, the first metal seed layer may be formed on an outer portion 300 of the base wafer W1 in order to electrically connect a plating electrode (not shown), such as a cathode, with the base wafer W1.

Referring again to FIG. 6, operation S13 may include coating the base adhesive layer 13 on the base wafer W1 and removing a portion of the base adhesive layer 13 corresponding to the base edge terminal 5 to expose the base edge terminal metal seed layer 25 formed on the circuit of the base chip 1 via the space A.

The base adhesive layer 13 may be obtained by coating a photosensitive adhesive capable of forming patterns. Also, the base adhesive layer 13 may be partially removed by etching a photosensitized or unphotosensitized portion.

Referring again to FIG. 7, in operation S21, at least one circuit of the stack chip 2 is formed on the stack wafer W2. Thus, a stack edge terminal 9, a stack edge pad 10, and a stack cut line L2 may be separately formed on the circuit of the stack chip 2.

As shown in FIG. 4, operation S21 may further include operation S22 in which a stack edge terminal metal seed layer 29 may be formed on a portion of the circuit of the stack chip 2, which corresponds to the stack edge terminal 9, such that the stack edge terminal 9 may be plated with a metal component.

Operation S22 may include forming a second metal seed layer on the stack wafer W2, coating photoresist on the second metal seed layer, exposing the photoresist to light, and etching the remaining portion of the second metal seed layer other than stack edge terminal metal seed layer 29 corresponding to the stack edge terminal 9.

Furthermore, operation S21 may further include operation S23 in which a stack adhesive layer 14 may be formed on the circuit of the stack chip 2.

Operation S23 may include coating the stack adhesive layer 14 on the stack wafer W2 and removing a portion of the stack adhesive layer 14 corresponding to the stack edge terminal 9 to expose the stack edge terminal metal seed layer 29 formed on the circuit of the stack chip 2 via the space B.

The stack adhesive layer 14 may be obtained by coating a photosensitive adhesive capable of forming patterns. Also, the stack adhesive layer 14 may be partially removed by etching a photosensitized or unphotosensitized portion.

Referring again to FIG. 8, in operation S24, the stack wafer W2 may be cut along the stack cut line L2, thereby forming the individual stack chips 2.

Referring again to FIG. 9, in operation S31, a stack chip 2 may be stacked on the base adhesive layer 13, and further individual stack chips 2 may be stacked on the stack adhesive layer 14.

In this case, the base edge terminal metal seed layer 25 of the base chip 1 and the stack edge terminal metal seed layer 29 of the stack chip 2 may be partially exposed by the spaces A and B.

Referring again to FIGS. 10, and referring to FIG. 11, operation S32 may include coating photoresist 100 both on the stack chip 2 stacked on the base chip 1 and on the base chip 1, exposing the photoresist 100 to light, etching the photoresist 100 to form a space C in a portion corresponding to the signal transmission member 4, and substantially filling the space C corresponding to the signal transmission member 4 with a metal post 15 using a plating process. As a result, as shown in FIG. 11, the signal transmission member 4 for electrically connecting the base chip 1 and the stack chip 2 may be obtained.

FIG. 12 is a cross-sectional view of the base wafer W1, which is cut along a base cut line L1 during operation S33 of FIG. 4 according to an embodiment of the present invention.

Referring to FIG. 12, in operation S33, the base wafer W1, which may include the signal transmission member 4, may be cut along the base cut line L1, thereby completing the base chip 1 on which the stack chip 2 is stacked. In this case, the base wafer W1 may be cut along the base cut line L1 using a laser cutting device 200. The laser cutting device 200 may be replaced by various other sawing devices, but the laser cutting device 200 is best suited to achieve delicate and rapid cutting performance.

According to embodiments of the present invention as described above, the fabrication process of a stack-type semiconductor package may be simplified and the number of process operations may be lessened, thereby reducing the production time and cost. Also, a state of electrical contact of a terminal with a signal transmission member may be solidified, thereby improving the reliability of the stack-type semiconductor package. Furthermore, new post-type signal transmission members are adopted instead of wires or electrodes so that the structural stability and productivity of the stack-type semiconductor package may be markedly enhanced.

While the present invention has been particularly shown and described with reference to exemplary embodiments thereof, it will be understood by one of ordinary skill in the art that various changes in form and details may be made therein without departing from the spirit and scope of the present invention as defined by the following claims.

What is claimed is:

1. A stack-type semiconductor package comprising:
a base chip having a circuit formed on one surface of the base chip;
at least one stack chip having a circuit formed on one surface of the stack chip, the stack chip stacked on the base chip;
an adhesive interposed between the base chip and the stack chip; and
signal transmission members formed along a lateral surface of the stack chip.

2. The package of claim 1, wherein the circuit of the base chip includes a base edge terminal that extends to the signal transmission members.

3. The package of claim 2, wherein the circuit of the base chip includes a base edge pad that is connected to the base edge terminal.

4. The package of claim 3, wherein the circuit of the base chip includes a base center pad that is connected to the base edge pad by a base connection circuit.

5. The package of claim 1, wherein the circuit of the stack chip includes a stack edge terminal that extends to an outer portion of the stack chip.

6. The package of claim 5, wherein the circuit of the stack chip includes a stack edge pad that is connected to the stack edge terminal.

7. The package of claim 6, wherein the circuit of the stack chip includes a stack center pad that is connected to the stack edge pad by a stack connection circuit.

8. The package of claim 1, wherein the adhesive comprises:
a base adhesive layer substantially covering the circuit of the base chip to protect the circuit of the base chip and including a first space to expose a surface of a base edge terminal of the base chip; and
a stack adhesive layer substantially covering the circuit of the stack chip to protect the circuit of the stack chip and including a second space to expose a surface of a stack edge terminal of the stack chip.

9. The package of claim 8, wherein each of the signal transmission members includes a conductive post substantially filling in the first space of the base adhesive layer and the second space of the stack adhesive layer.

10. The package of claim 9, wherein a metal seed layer used for plating is formed on each of the exposed base edge terminal of the base chip and the exposed stack edge terminal of the stack chip, and each of the signal transmission members includes a metal post, which is plated on the metal seed layer to substantially fill the first space of the base adhesive layer and the second space of the stack adhesive layer.

11. The package of claim 1, wherein the adhesive includes a photosensitive adhesive capable of forming patterns.

12. The package of claim 1, wherein the stack chip is substantially adhered using the adhesive onto a top surface of the circuit of the base chip of a base wafer.

13. The package of claim 1, wherein a support portion for supporting the signal transmission members is formed along an outer portion of the base chip.

14. A stack-type semiconductor package comprising:
a base chip having a circuit formed on one surface of the base chip, the base chip including a base edge terminal connected to the circuit of the base chip;
at least one stack chip stacked on the base chip and having a circuit formed on one surface of the stack chip, the stack chip including a stack edge terminal connected to the circuit of the stack chip;
an adhesive interposed between the base chip and the stack chip and forming a first space to expose the base edge terminal of the base chip and a second space to expose the stack edge terminal of the stack chip; and
signal transmission members substantially filling in the first and second spaces of the adhesive to electrically connect the base edge terminal of the base chip and the stack edge terminal of the stack chip, the signal transmission members formed along a lateral surface of the stack chip.

15. A method of fabricating a stack-type semiconductor package, the method comprising:
forming a base chip having a circuit;
forming a stack chip having a circuit;
forming an adhesive layer on a surface of the base chip;
stacking the stack chip on the base chip, wherein the adhesive layer is interposed between the stack chip and the base chip; and
forming signal transmission members along a lateral surface of the stack chip.

16. The method of claim 15, the method further comprising:
forming an adhesive layer on a surface of the stack chip.

17. The method of claim 16, wherein:
the forming of the adhesive layer on the surface of the base chip includes substantially covering the circuit of the base chip to protect the circuit of the base chip, and forming a first space to expose a surface of a base edge terminal of the base chip; and
the forming of the adhesive layer on the surface of the stack chip includes substantially covering the circuit of the stack chip to protect the circuit of the stack chip, and forming a second space to expose a surface of a stack edge terminal of the stack chip.

18. The method of claim 17, wherein the forming of the signal transmission members further comprises:
forming a conductive post substantially filling in the first space of the base adhesive layer and the second space of the stack adhesive layer.

19. The method of claim 18, wherein the forming of the conductive post further comprises:
forming a metal seed layer used for plating on each of the exposed base edge terminal of the base chip and the exposed stack edge terminal of the stack chip; and
forming of a metal post which is plated on the metal seed layer to substantially fill the first space of the base adhesive layer and the second space of the stack adhesive layer.
